(19) United States
(12) Patent Application Publication
(10) Pub. No.: US 2011/0317803 A1
(43) Pub. Date: Dec. 29, 2011

(54) SHIFT REGISTER CIRCUIT AND SHIFT REGISTER

(75) Inventors: Chen-Lun CHIU, Hsin-Chu (TW); Yi-Suei Liao, Hsin-Chu (TW); Ping-Lin Chen, Hsin-Chu (TW); Kuan-Yu Chen, Hsin-Chu (TW)

(73) Assignee: AU OPTRONICS CORP., HSINCHU (TW)

(21) Appl. No.: 13/042,702

(22) Filed: Mar. 8, 2011

(30) Foreign Application Priority Data
Jun. 23, 2010 (TW) 099120531

(51) Int. Cl. G11C 19/00

(52) U.S. Cl. 377/67; 377/64

(57) ABSTRACT

An exemplary shift register circuit includes a plurality of shift registers for sequentially outputting a plurality of driving pulse signals. Among each M number of the shift registers for sequentially outputting M number of the driving pulse signals, the shift register for lastly outputting one of the M number of driving pulse signals is enabled, by (M−1) number of start pulse signals sequentially outputted from the remained (M−1) number of the shift registers, to generate the driving pulse signal. Herein, M is a positive integer greater than 2. Moreover, a circuit structure of a shift register also is provided.

### BACKGROUND

1. Technical Field

The present invention generally relates to display fields and, particularly to a shift register circuit and a circuit structure of a shift register.

2. Description of the Related Art

A liquid crystal display device using shift registers manufactured by an amorphous silicon process in a gate driving circuit thereof is a mainstream of current thin film transistor liquid crystal display (TFT-LCD) technology, and has advantages of reducing cost of integrated circuit (IC), simplifying module manufacturing process and increasing utilization efficiency of glass substrate, etc. Herein, a shift register circuit generally includes a plurality of shift registers connected in cascade, for sequentially outputting a plurality of driving pulse signals. The driving pulse signals generated by the respective shift registers each would act as a start pulse signal of the next-staged shift register.

However, in some severe environments, e.g., low temperature, when a display panel is operated, a conduction current of thin film transistor in the display panel would fall dramatically resulting from the low temperature, so that the shift register circuit using amorphous silicon will encounter the issue of the gate driving pulse signal would not be normally generated, resulting in the panel would not be normally driven. Although the issue can be overcome by attempting to increase the operating voltage of the shift registers, such attempt would increase the operating power of the shift register circuit, it is extremely disadvantageous to portable display devices.

### SUMMARY OF THE INVENTION

Accordingly, the present invention is directed to a shift register circuit, which still can normally produce a driving pulse signal even if a conduction current of transistor is low in low temperature environment, so that the issue of low temperature start is solved.

The present invention is further directed to a shift register, which can solve the issue of low temperature start in the prior art.

More specifically, a shift register circuit in accordance with an embodiment of the present invention includes a plurality of shift registers. The shift registers are for sequentially outputting a plurality of driving pulse signals. Among each M number of the shift registers for sequentially outputting M number of the driving pulse signals, the shift register for lastly outputting one of the M number of driving pulse signals is enabled, by (M−1) number of start pulse signals sequentially outputted from the other (M−1) number of shift registers, to generate the driving pulse signal. M is a positive integer in the range of greater than 2 and less than 5.

In one embodiment, the shift register for lastly outputting the driving pulse signal includes a pull-up circuit, a driving circuit and a pull-down circuit. The pull-up circuit includes a plurality of switching elements, and output terminals of the switching elements are electrically coupled to a common node. The switching elements respectively are subjected to the control of the (M−1) number of start pulse signals and deliver the (M−1) number of start pulse signals to the common node. The driving circuit includes a control terminal, an input terminal and an output terminal. The control terminal of the driving circuit is electrically coupled to the common node, the input terminal of the driving circuit is electrically coupled to receive a clock signal, and the output terminal of the driving circuit is for outputting the driving pulse signal according to the clock signal when the control terminal is enabled. The pull-down circuit is electrically coupled to the common node and the output terminal of the driving circuit, for pulling voltages at the common node and the output terminal of the driving circuit down to a predetermined voltage.

In one embodiment, each of the switching elements is a transistor, a gate of the transistor is electrically coupled to receive a corresponding one of the (M−1) number of start pulse signals, a first source/drain of the transistor is electrically coupled to the gate, and a second source/drain of the transistor is electrically coupled to the common node.

In one embodiment, active periods of the duty cycles of the (M−1) number of start pulse signals are partially overlapped with one another.

In another embodiment, active periods of the duty cycles of the (M−1) number of start pulse signals are mutually non-overlapped.

A shift register in accordance with an embodiment of the present invention includes a pull-up circuit, a driving circuit and a pull-down circuit. The pull-up circuit is subjected to the control of a plurality of sequentially-provided pulse signals and delivers the pulse signals to an output terminal of the pull-up circuit. The driving circuit includes a control terminal, an input terminal and an output terminal. The control terminal of the driving circuit is electrically coupled to the output terminal of the pull-up circuit, the input terminal of the driving circuit is electrically coupled to receive a clock signal, and the output terminal of the driving circuit is for outputting a driving pulse signal according to the clock signal when the control terminal is enabled. The pull-down circuit is electrically coupled to the output terminal of the pull-up circuit and the output terminal of the driving circuit, for pulling voltages at the output terminal of the pull-up circuit and the output terminal of the driving circuit down to a predetermined voltage.

In one embodiment, the pull-up circuit of the shift register includes a plurality of switching elements, and the switching elements respectively are subjected to the control of the pulse signals and deliver the pulse signals to the output terminal of the pull-up circuit. Moreover, the switching elements each can be a transistor, a gate of the transistor is electrically coupled to receive a corresponding one of the pulse signals, a first source/drain of the transistor is electrically coupled to the gate, and a second source/drain of the transistor is electrically coupled to the output terminal of the pull-up circuit.

In one embodiment, active periods of the duty cycles of the sequentially-provided pulse signals are partially overlapped with one another. Alternatively, the active periods of the duty cycles of the sequentially-provided pulse signals are mutually non-overlapped.

A shift register circuit in accordance with another embodiment of the present invention includes a plurality of shift registers. The shift registers are for sequentially outputting a plurality of driving pulse signals. Active periods of the duty cycles of M number of the driving pulse signals are partially overlapped with one another, M is a positive integer and greater than 2. Among M number of the shift registers for sequentially outputting the M number of driving pulse signals, the shift register for lastly outputting one of the M number of driving pulse signals is enabled, by a start pulse signal outputted from a previous Kth shift register, to generate the driving pulse signal, wherein K is a positive integer greater than or equal to 2.

In one embodiment, an active period of the duty cycle of the start pulse signal and the active period of the duty cycle of the lastly outputted driving pulse signal are mutually non-overlapped.

In one embodiment, the shift register for lastly outputting the driving pulse signal includes a pull-up circuit, a driving circuit and a pull-down circuit. The pull-up circuit includes a switching element, and the switching element is subjected to the control of the start pulse signal and delivers the start pulse signal to an output terminal of the pull-up circuit. The driving circuit includes a control terminal, an input terminal and an output terminal. The control terminal of the driving circuit is electrically coupled to the output terminal of the pull-up circuit, the input terminal of the driving circuit is electrically coupled to receive a clock signal, and the output terminal of the driving circuit is for outputting the driving pulse signal according to the clock signal when the control terminal is enabled. The pull-down circuit is electrically coupled to the output terminal of the pull-up circuit and the output terminal of the driving circuit, for pulling voltages at the output terminal of the pull-up circuit and the output terminal of the driving circuit down to a predetermined voltage.

In one embodiment, the switching element is a transistor, a gate of the transistor is electrically coupled to receive the start pulse signal, a first source/drain of the transistor is electrically coupled to the gate, and a second source/drain of the transistor is electrically coupled to the output terminal of the pull-up circuit.

In the various embodiments of the present invention, by the specific design for the circuit structure of shift register and/or re-arrangement of electrical connection relationships among the shift registers in the shift register circuit, so as to increase the charging times of gate voltage of the transistors in the respective shift registers for outputting the driving pulse signals, so that the shift registers still can normally produce the driving pulse signals even if in low temperature environment, and thereby can effectively solve the issue of low temperature start associated with the prior art without increasing the operating voltage of shift register.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 shows a schematic, partial structural view of a shift register circuit in accordance with a first embodiment of the present invention.

FIG. 2 shows an internal circuit structure diagram of any one of the shift registers in the shift register circuit as shown in FIG. 1.

FIGS. 3A and 3B respectively show two different timing sequence relationships between two start pulse signals used by the shift register as shown in FIG. 2.

FIG. 4 shows a schematic, partial structural view of a shift register circuit in accordance with a second embodiment of the present invention.

FIG. 5 shows an internal circuit structure diagram of any one of the shift registers in the shift register circuit as shown in FIG. 4.

FIG. 6 show a timing diagram associated with multiple gate driving pulse signals and multiple start pulse signals as shown in FIG. 4.

### DETAILED DESCRIPTION

It is to be understood that other embodiment may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted,” and variations thereof herein are used broadly and encompass direct and indirect connections, couplings, and mountings. Accordingly, the descriptions will be regarded as illustrative in nature and not as restrictive.

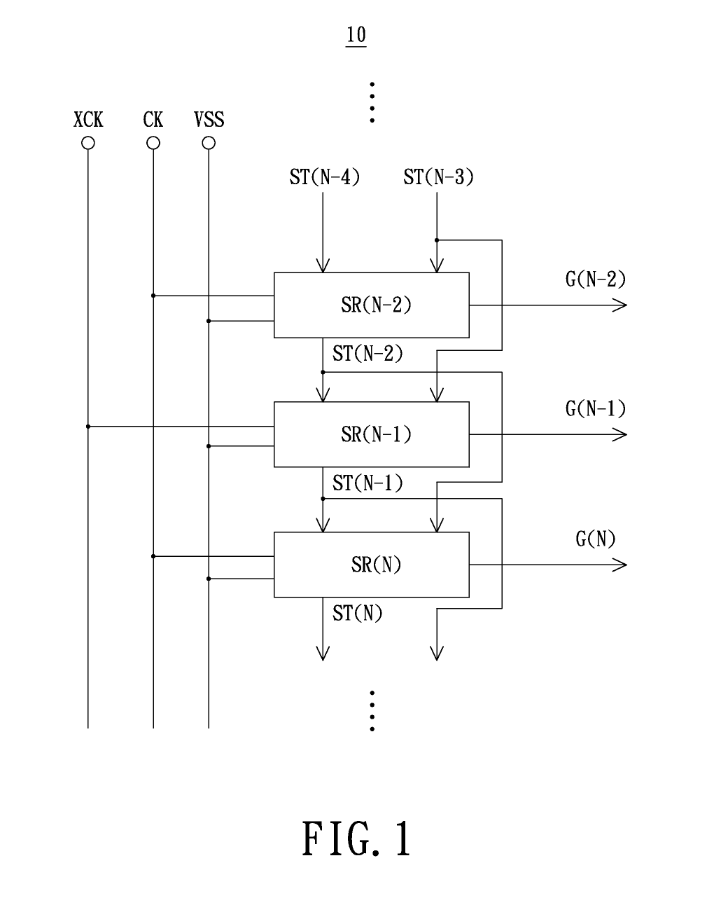

Referring to FIG. 1, a schematic partial structural view of a shift register circuit in accordance with a first embodiment of the present invention is shown. As illustrated in FIG. 1, the shift register circuit 10 is adapted to a gate driving circuit of a display device, but does not limit the present invention, for example the shift register circuit 10 also can be adapted to a source driving circuit of the display device. In particular, the shift register circuit 10 includes a plurality of shift registers, for example SR(N−2), SR(N−1) and SR(N), for generating gate driving pulse signals using multi-phase clocks e.g., two-phase clocks XCK, CK, but not to limit the present invention. In the illustrated embodiment, the shift registers SR(N−2), SR(N−1) and SR(N) are for sequentially generating gate driving pulse signals G(N−2), G(N−1) and G(N), and N is a positive integer.

More specifically, the shift register SR(N−2) is electrically coupled to a power supply voltage VSS and subjected to the control of the clock signal CK and start pulse signals ST(N−4), ST(N−3) to generate a gate driving pulse signal G(N−2) and a start pulse signal ST(N−2). Herein, the start pulse signal ST(N−2) and the gate driving pulse signal G(N−2) have a same timing sequence. The shift register SR(N−1) is electrically coupled to the power supply voltage VSS and subjected to the control of another clock signal XCK and the start pulse signals ST(N−3), ST(N−2) to generate another gate driving pulse signal G(N−1) and a start pulse signal ST(N−1). Herein, the start pulse signal ST(N−1) and the gate driving pulse signal G(N−1) have a same timing sequence. The shift register SR(N) is electrically coupled to the power supply voltage VSS and subjected to the control of the clock signal CK and the start pulse signals ST(N−2), ST(N−1) to generate the gate driving pulse signal G(N) and a start pulse signal ST(N). Herein, the start pulse signal ST(N) and the gate driving pulse signal G(N) have a same timing sequence. In short, among the three shift registers SR(N−2). SR(N−1) and SR(N) for sequentially outputting three gate driving pulse signals e.g., G(N−2), G(N−1) and G(N), the shift register SR(N) for lastly outputting the gate driving pulse signal G(N) is enabled by the two start pulse signals ST(N−2), ST(N−1) sequentially outputted from the two shift registers SR(N−2), SR(N−1) for outputting the preceding gate driving pulse signals G(N−2), G(N−1), to generate the gate driving pulse signal G(N).

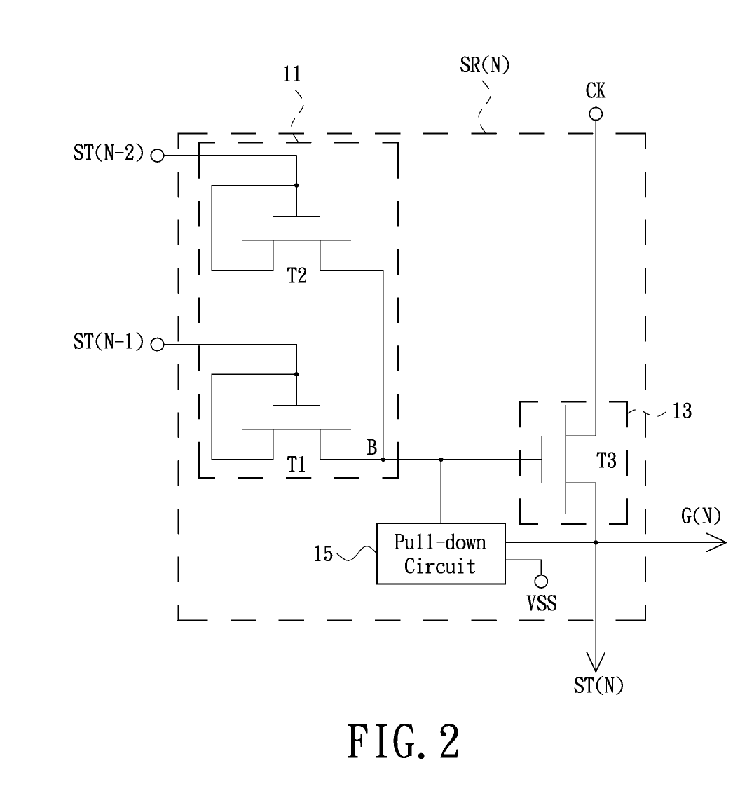

Referring to FIG. 2, showing an internal circuit diagram of any one of the shift registers e.g., SR(N) in the shift register circuit 10 associated with the first embodiment of the present invention. As illustrated in FIG. 2, the shift register SR(N) includes a pull-up circuit 11, a driving circuit 13 and a pull-down circuit 15. The pull-up circuit 11 includes transistors T1, T2 as switching elements. One of the source/drain electrodes of each of the transistors T1, T2 is electrically coupled to a common node B, the other one of the drain/source electrodes of the transistor T1 is electrically coupled to the gate of the transistor T1, and the other one of the drain/source electrodes of the transistor T2 is electrically coupled to the gate of the transistor T2. The transistors T1, T2 are subjected to the controls of the respective start pulse signals ST(N−1), ST(N−2) through the gates thereof and deliver the start pulse signals ST(N−1), ST(N−2) to the common node B, so as to charge the common node B. The driving circuit 13 includes a transistor T3. The gate of the transistor T3 is electrically couple with the common node B and acts as a control terminal, one of the drain/source electrodes of the transistor T3 acts as an input terminal for receiving the clock signal CK, and the other one of the source/drain electrodes of the transistor T3 acts as an output terminal for outputting the gate driving pulse signal G(N) according to the clock signal CK. The pull-down circuit 15 is electrically coupled to the common node B and the output terminal of the transistor T3, for pulling voltages at the common node B and the output terminal of the transistor T3 down to a predetermined voltage e.g., the power supply voltage VSS during the output of gate driving pulse signal G(N) is disabled.

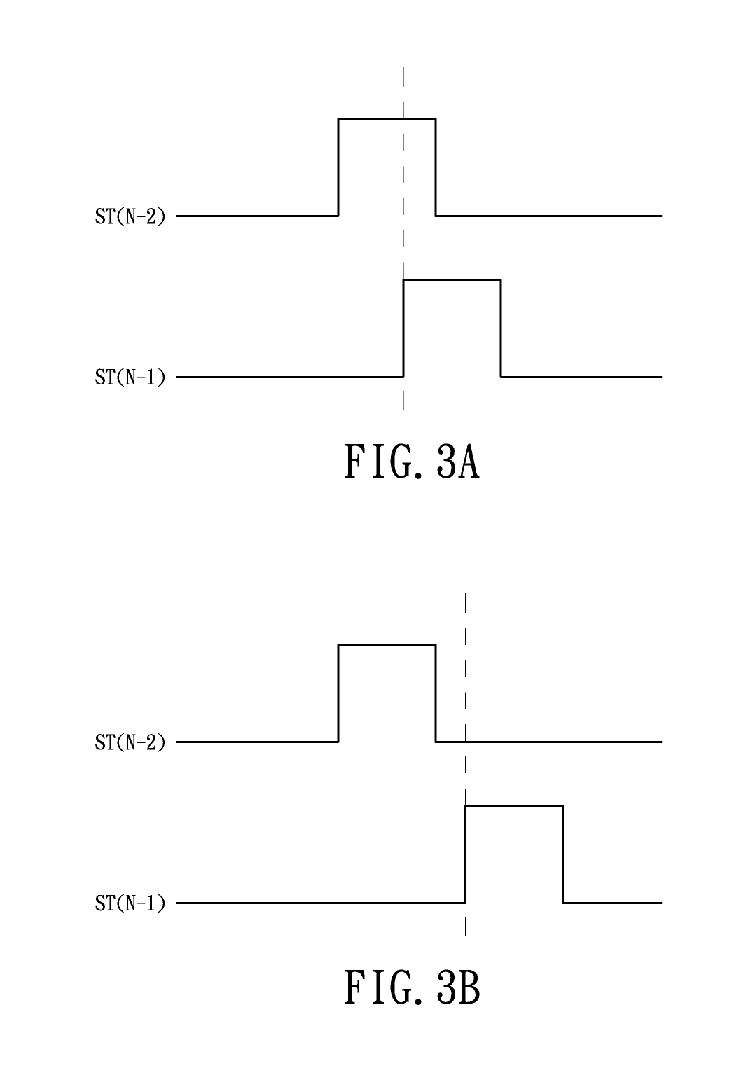

Referring to FIGS. 3A and 3B, showing two different timing sequence relationships between the start pulse signals ST(N−2) and ST(N−1). In FIG. 3A, duty-on cycles (i.e., HIGH level cycles) of the start pulse signals ST(N−2) and ST(N−1) are partially overlapped with each other. In FIG. 3B, the duty-on cycles of the start pulse signals ST(N−2) and ST(N−1) are mutually non-overlapped. Since the prior art only uses the start pulse signal ST(N−1) generated from the preceding-staged shift register SR(N−1) to charge the node B, when the shift register SR(N) is in low temperature environment resulting in a conduction current of the transistor T1 is not enough, the voltage at the node B would not be charged to an enough voltage level and thus the gate driving pulse signal G(N) would not be normally generated. However, in the illustrated embodiment, since the shift register SR(N) receives the start pulse signals ST(N−2), ST(N−1) generated from the two preceding-staged shift registers SR(N−2), SR(N−1) to charge the common node B, even if the transistors T1, T2 are operated in low temperature environment, the voltage at the common node B can be charged by the sequentially-generated two start pulse signals ST(N−2), ST(N−1), so that the charging time of the common node B is increased and thereby achieving the effect of normally generating a gate driving pulse signal at low temperature. It is indicated that, the shift register SR(N) is not limited to use two start pulse signals to charge the common node B, and may use three or even more start pulse signals to charge the common node B according to the actual requirement, and correspondingly the amount of transistors in the pull-up circuit 11 ought to be increased.

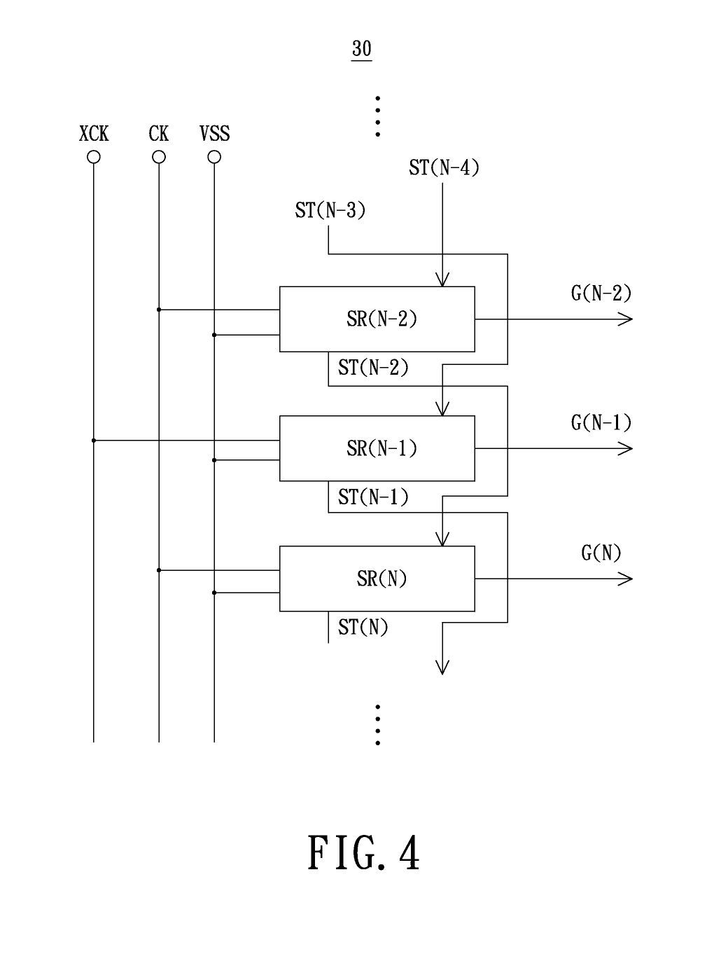

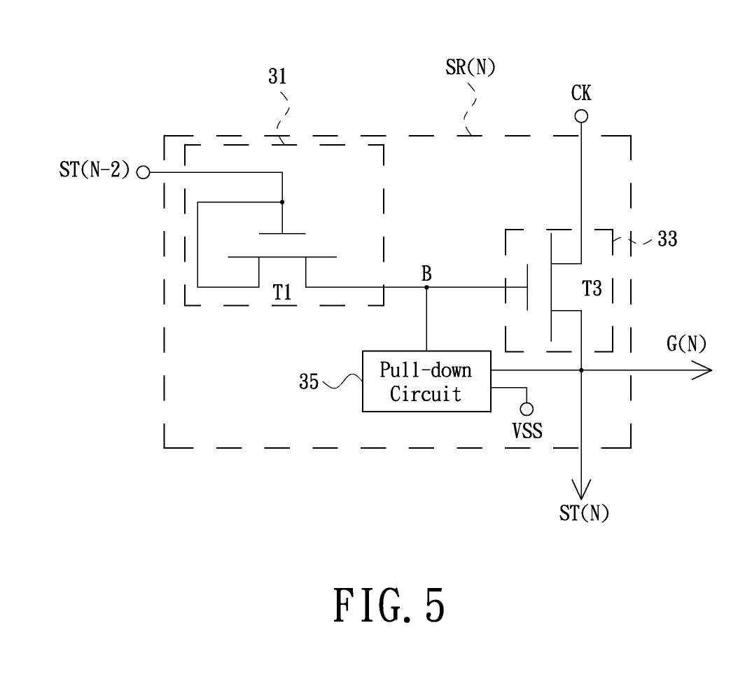

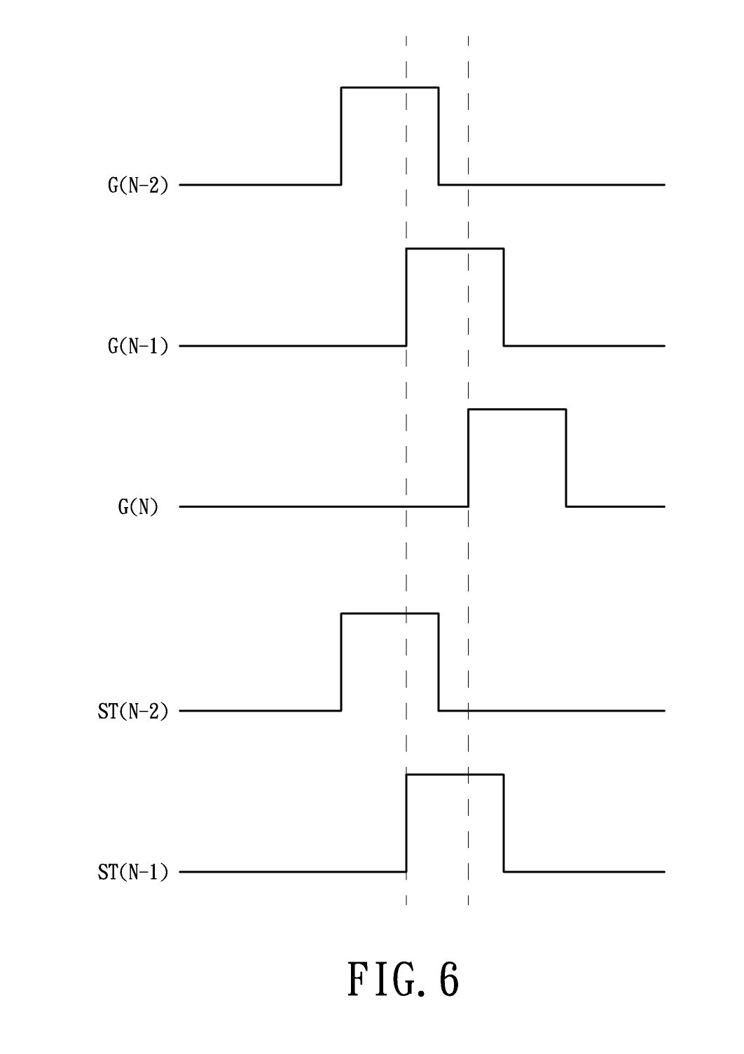

In the first embodiment of the present invention, by changing the internal circuit structure of the shift registers (e.g., increasing the transistor T2 in the pull-up circuit 11) and correspondingly adjusting the electrical connection relationships among the three shift registers SR(N−2)˜SR(N) (even more than three, but preferably is less than five) in the shift register circuit 10 to solve the issue of low temperature start in the prior art, but it does not to limit the present invention, and may only change the electrical connection relationships among the shift registers in the shift register circuit while do not change the internal circuit structures of the shift registers to solve the issue of low temperature start in the prior art, for example an implementation as illustrated in FIG. 4, FIG. 5 and FIG. 6.

Referring to FIG. 4, a schematic partial structural view of a shift register circuit in accordance with a second embodiment of the present invention is shown. As illustrated in FIG. 4, the shift register circuit 30 is adapted to a gate driving circuit of a display device, but not to limit the present invention, and may be applied to a source driving circuit of the display device. In particular, the shift register circuit 30 includes a plurality of shift registers e.g., SR(N−2), SR(N−1) and SR(N), using multi-phase clocks e.g., two-phase clocks XCK, CK to generate gate driving pulse signals. In the illustrated embodiment, the shift registers SR(N−2), SR(N−1) and SR(N) are for sequentially generating gate driving pulse signals G(N−2), G(N−1) and G(N), N is a positive integer.

More specifically, the shift register SR(N−2) is electrically coupled to the power supply voltage VSS and subjected to the control of the clock signal CK and a start pulse signal ST(N−4) to generate the gate driving pulse signal G(N−2) and a start pulse signal ST(N−2). The shift register SR(N−1) is electrically coupled to the power supply voltage VSS and subjected to the control of the clock signal XCK and a start pulse signal ST(N−3) to generate the gate driving pulse signal G(N−1) and a start pulse signal ST(N−1). The shift register SR(N) is electrically coupled to the power supply voltage VSS and subjected to the control of the clock signal CK and the start pulse signal ST(N−2) to generate the gate driving pulse signal G(N) and a start pulse signal ST(N).

Referring to FIG. 5, showing an internal circuit diagram of any one of the shift registers e.g., SR(N) in the shift register circuit 30 associated with the second embodiment of the present invention. As illustrated in FIG. 5, the shift register SR(N) includes a pull-up circuit 31, a driving circuit 33 and a pull-down circuit 35. The pull-up circuit 31 includes a transistor T1 acts as a switching element. One of the source/drain electrodes of the transistor T1 is electrically coupled to the node B, and the other one of the drain/source electrodes of the transistor T1 is electrically coupled to the gate of the transistor T1. The transistor T1 is subjected to the control of the start pulse signal ST(N−2) through the gate thereof and delivers the start pulse signal ST(N−2) to the node B. The driving circuit 33 includes a transistor T3. The gate of the transistor T3 is electrically couple to the node B and acts as a control terminal, one of the drain/source electrodes of the transistor T3 acts as an input terminal for receiving the clock signal CK, and the other one of the source/drain electrodes of the transistor T3 acts as an output terminal for outputting the gate driving pulse signal G(N) according to the clock signal CK. The pull-down circuit 35 is electrically coupled to the node B and the output terminal of the transistor T3, for pulling voltages at the node B and the output terminal of the transistor T3 down to a predetermined voltage e.g., the power supply voltage VSS during the output of gate driving pulse signal G(N) is disabled.

Referring to FIGS. 4 through 6 together, wherein FIG. 6 shows a timing diagram of sequentially-generated gate driving pulse signals G(N−2), G(N−1), G(N) and the start pulse signals ST(N−2), ST(N−1). In FIG. 6, duty-on cycles of each adjacent two of the gate driving pulse signals G(N−2), G(N−1) and G(N) are partially overlapped with each other, timing sequences of the start pulse signals ST(N−2), ST(N−1) respectively are the same as that of the gate driving pulse signals G(N−2), G(N−1). In the illustrated embodiment, for any one of the shift registers e.g., SR(N) in the shift register circuit 30, the start pulse signal used by the pull-up circuit 31 is not the ST(N−1) generated from the nearest preceding-staged shift register SR(N−1) as in the prior art, but is the start pulse signal generated from another preceding-staged shift register SR(N−2). Moreover, the duty-on cycles of the start pulse signal ST(N−2) used in the present embodiment and the gate driving pulse signal G(N) are mutually non-overlapped, so that the charging time of the node B is prolonged with respect to that in the prior art and thus also can solve the issue of low temperature start.

It is noted that, in the second embodiment of the present invention, any one shift register e.g., SR(N) is not limited to use the start pulse signal ST(N−2) as described above, and can use the start pulse signal ST(N−K) generated from any preceding-staged shift register except the SR(N−1) according to the actual requirement, so as to achieve the effect of prolong the charging time of the node B, K is no less than 2.

In summary, in the various embodiments of the present invention, by the specific design for the circuit structure of shift register and/or re-arrangement of electrical connection relationships among the shift registers in the shift register circuit, for the purpose of increasing the charging times of gate voltage of the transistors in the respective shift registers for outputting the driving pulse signals, so that the shift registers still can normally produce the driving pulse signals even if in low temperature environment, and thereby can effectively solve the issue of low temperature start associated with the prior art without increasing the operating voltage of shift register.

The above description is given by way of example, and not limitation. Given the above disclosure, one skilled in the art could devise variations that are within the scope and spirit of the invention disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. A shift register circuit comprising:
a plurality of shift registers, for sequentially outputting a plurality of driving pulse signals;
wherein among each M number of the shift registers for sequentially outputting M number of the driving pulse signals, the shift register for lastly outputting one of the M number of driving pulse signals receives (M−1) number of start pulse signals sequentially outputted from the other (M−1) number of shift registers and then generates the driving pulse signal outputted therefrom, M is a positive integer greater than 2.

2. The shift register circuit as claimed in claim 1, wherein among each M number of the shift registers for sequentially outputting the M number of driving pulse signals, the shift register for lastly outputting the driving pulse signal comprises:
a pull-up circuit, comprising a plurality of switching elements, wherein output terminals of the switching elements are electrically coupled to a common node, the switching elements are respectively subjected to the control of the (M−1) number of start pulse signals and deliver the (M−1) number of start pulse signals to the common node;
a driving circuit, comprising a control terminal, an input terminal, and an output terminal, wherein the control terminal is electrically coupled to the common node, the input terminal is electrically coupled to receive a clock signal, and the output terminal of the driving circuit is for outputting the driving pulse signal according to the clock signal when the control terminal is enabled; and
a pull-down circuit, electrically coupled to the common node and the output terminal of the driving circuit, for pulling voltages at the common node and the output terminal of the driving circuit down to a predetermined voltage.

3. The shift register circuit as claimed in claim 2, wherein each of the switching elements is a transistor, a gate of the transistor is electrically coupled to receive a corresponding one of the (M−1) number of start pulse signals, a first source/drain of the transistor is electrically coupled to the gate, and a second source/drain of the transistor is electrically coupled to the common node.

4. The shift register circuit as claimed in claim 1, wherein active periods of the duty cycles of the (M−1) number of start pulse signals are partially overlapped with one another.

5. The shift register circuit as claimed in claim 1, wherein active periods of the duty cycles of the (M−1) number of start pulse signals are mutually non-overlapped.

6. The shift register circuit as claimed in claim 1, wherein M is a positive integer less than 5.

7. A shift register comprising:
a pull-up circuit, subjected to the control of a plurality of sequentially-provided pulse signals and delivering the pulses signals to an output terminal of the pull-up circuit;
a driving circuit, comprising a control terminal, an input terminal, and an output terminal, wherein the control terminal of the driving circuit is electrically coupled to the output terminal of the pull-up circuit, the input terminal of the driving circuit is electrically coupled to receive a clock signal, and the output terminal of the driving circuit is for outputting a driving pulse signal according to the clock signal when the control terminal is enabled; and
a pull-down circuit, electrically coupled to the output terminal of the pull-up circuit and the output terminal of the driving circuit, for pulling voltages at the output terminal of the pull-up circuit and the output terminal of the driving circuit down to a predetermined voltage.

8. The shift register as claimed in claim 7, wherein the pull-up circuit comprises a plurality of switching elements, the switching elements are subjected to the control of the respective pulse signals and then deliver the pulse signals to the output terminal of the pull-up circuit.

9. The shift register as claimed in claim 8, wherein each of the switching elements is a transistor, a gate of the transistor is electrically coupled to receive a corresponding one of the pulse signals, a first source/drain of the transistor is electrically coupled to the gate, and a second source/drain of the transistor is electrically coupled to the output terminal of the pull-up circuit.

10. The shift register as claimed in claim 7, wherein active periods of the duty cycles of the pulse signals are partially overlapped with one another.

11. The shift register as claimed in claim 7, wherein active periods of the duty cycles of the pulse signals are mutually non-overlapped.

12. A shift register circuit comprising:
a plurality of shift registers for sequentially outputting a plurality of driving pulse signals, and active periods of the duty cycles of M number of sequentially-outputted driving pulse signals among the driving pulse signals being partially overlapped with one another, M being a positive integer greater than 2;
wherein among M number of the shift registers for sequentially outputting the M number of driving pulse signals, the shift register for lastly outputting one of the M number of driving pulse signals is enabled by a start pulse signal outputted from a previous Kth shift register, to generate the driving pulse signal outputted therefrom, where K is a positive integer greater than or equal to 2.

13. The shift register circuit as claimed in claim 12, wherein an active period of the duty cycle of the start pulse signal and the active period of the duty cycle of the lastly-outputted driving pulse signal in the M number of driving pulse signals are mutually non-overlapped.

14. The shift register circuit as claimed in claim 12, wherein among the M number of shift registers for sequentially outputting the M number of sequentially-outputted driving pulse signals, the shift register for lastly outputting the driving pulse signal comprises:
a pull-up circuit, comprising a switching element, wherein the switching element is subjected to the control of the start pulse signal and delivers the start pulse signal to an output terminal of the pull-up circuit;
a driving circuit, comprising a control terminal, an input terminal and an output terminal, wherein the control terminal of the driving circuit is electrically coupled to the output terminal of the pull-up circuit, the input terminal of the driving circuit is electrically coupled to receive a clock signal, and the output terminal of the driving circuit is for outputting the driving pulse signal according to the clock signal when the control terminal is enabled; and
a pull-down circuit, electrically coupled to the output terminal of the pull-up circuit and the output terminal of the driving circuit, for pulling voltages at the output terminal of the pull-up circuit and the output terminal of the driving circuit down to a predetermined voltage.

15. The shift register circuit as claimed in claim 14, wherein the switching element is a transistor, a gate of the transistor is electrically coupled to receive the start pulse signal, a first source/drain of the transistor is electrically coupled to the gate, and a second source/drain of the transistor is electrically coupled to the output terminal of the pull-up circuit.

16. The shift register circuit as claimed in claim 12, wherein M is a positive integer less than 5.
